(19) United States
(12) Patent Application Publication
(10) Pub. No.: US 2006/0119451 A1
(43) Pub. Date: Jun. 8, 2006

(54) Switching circuits

(75) Inventor: Po-Yu Chen, Taipei City (TW)

Correspondence Address: BIRCH STEWART KOLASCH & BIRCH, PO BOX 747, FALLS CHURCH, VA, 22040-0747, US

(73) Assignee: Airoha Technology Corp.

(21) Appl. No.: 11/295,464

(22) Filed: Dec. 7, 2005

(30) Foreign Application Priority Data
Dec. 8, 2004 (TW) 93137896

(51) Int. Cl. H01P 1/15

(52) U.S. Cl. 333/103

(57) ABSTRACT

Switching circuits with reduced insertion loss. A first MOS element of a first conductive type is disposed in a substrate of a second conductive type, and comprises a first terminal coupled to an output/input terminal, a second terminal coupled to an antenna element, a control terminal coupled to a control signal, and a bulk terminal coupled to a first voltage through an external resistor. A deep well region of the first conductive type is disposed in the substrate, separating the first MOS element from the substrate.

### BACKGROUND OF THE INVENTION

1. Field of the Invention

The present invention relates to switching circuits, and in particular relates to radio frequency switch circuits with reduced insertion loss.

2. Description of the Related Art

As is well known, radio frequency (RF) switches are important in many different communications devices such as cellular telephones, wireless pagers, wireless infrastructure equipment, satellite communications equipment and cable television equipment. The performance of the RF switches, however, is controlled by three primary operating performance parameters: insertion loss, switch isolation and the “1 dB compression point”.

FIG. 1 shows a conventional single-pole double-throw (SPDT) RF switch. As shown, the SPDT RF switch comprises switching element M1˜M4, and insertion loss thereof can be improved by reducing or increasing bulk resistance according to small signal mode of the switching element M1/M2.

Feng-Jung Huang et al disclose increased contacts between bulk and ground such that total contact resistance and bulk resistance are lowered to reduce insertion loss, in IEEE J. Solid-State Circuits, vol. 36, No. 3, March 2001. This method, however, requires a large area to increase contacts. Further, RF switches are used between antenna and transmission/reception (TX/RX) terminals, and the power injected to the RF switches by power amplifiers at the transmission terminal often exceeds 10 dBm. The voltage level at drain/source terminal of the MOS transistor is lower than 0V due to voltage swing in a negative half period. Because the bulk terminal of the MOS transistor is grounded, there is a positive bias voltage between the PN junction between the drain/source terminal and the bulk terminal, inducing signal distortion.

As shown in FIG. 2, Niranjan et al disclose utilizing a LC parallel circuit to generate an impedance close to open-circuit at a desired frequency such that the bulk resistance approximates infinity, in IEEE J. Solid-State Circuits, vol. 39, No. 6, March 2004. Thus, optimum insertion loss is obtained at the desired frequency. However, the inductive element is required to have high Q value, in order to obtain an infinity impedance at the desired frequency by the LC parallel circuit. Low insertion loss bandwidth of the LC circuit reduces as the Q value increase. Namely, there is a trade-off between low insertion loss and broad bandwidth. Further, this method also requires large area due to the inductive elements. Moreover, the two described RF switches both suffer signal distortion under large power, and thus, require a DC bias voltage on the source/drain terminal of the MOS transistor.

### BRIEF SUMMARY OF INVENTION

A detailed description is given in the following embodiments with reference to the accompanying drawings.

Embodiments of a switching circuit are disclosed. A first MOS element of a first conductive type is disposed in a substrate of a second conductive type, and comprises a first terminal coupled to an output/input terminal, a second terminal coupled to an antenna element, a control terminal coupled to a control signal, and a bulk terminal coupled to a first voltage through an external resistor. A deep well region of the first conductive type is disposed in the substrate, separating the first MOS element from the substrate.

The invention also discloses another embodiment of the switching circuit, in which a first MOS element of a first conductive type is disposed in a substrate of a second conductive type, and comprises a first terminal coupled to an output/input terminal, a second terminal coupled to an antenna element, a control terminal coupled to a control signal, and a bulk terminal. A deep well region of the first conductive type is disposed in the substrate, separating the first MOS element from the substrate. A resistive element is coupled between the second terminal and the bulk terminal of the first MOS element.

The invention also discloses another embodiment of the switching circuit, in which a deep well region of the first conductive type is disposed in the substrate of a second conductive type. First and second MOS elements of a first conductive type are disposed in the deep well region of the first, each comprising a first terminal coupled to a first output/input terminal, a second terminal coupled to an antenna element, a control terminal coupled to a control signal, and a bulk terminal coupled to a first voltage through a first external resistor. A third MOS element of a second conductive type comprises a first terminal coupled to a second output/input terminal, a second terminal coupled to the antenna element, a control terminal coupled to an inversion signal of the control signal, and a bulk terminal coupled to the first voltage through a second external resistor, wherein the deep well region separates the first and second MOS elements of the first conductive type from the substrate of the second conductive type.

The invention also discloses another embodiment of the switching circuit, in which a deep well region of the first conductive type is disposed in the substrate of a second conductive type. A first MOS element of a first conductive type is disposed in deep well region, and comprises a first terminal coupled to a first output/input terminal, a second terminal coupled to an antenna element, a control terminal coupled to a control signal, and a bulk terminal. A first resistive element is coupled between the second terminal and the bulk terminal of the first MOS element. A second MOS element of the first conductive type comprises a first terminal coupled to a second output/input terminal, a second terminal coupled to the antenna element, a control terminal coupled to an inversion signal of the control signal, and a bulk terminal. A second resistive element is coupled between the second terminal and the bulk terminal of the second MOS element, and the deep well region separates the first and second MOS elements from the substrate.

### BRIEF DESCRIPTION OF DRAWINGS

The present invention can be more fully understood by reading the subsequent detailed description and examples with references made to the accompanying drawings, wherein:

FIG. 1 shows a conventional single-pole double-throw (SPDT) RF switch;

FIG. 2 shows another conventional single-pole double-throw (SPDT) RF switch;

FIG. 3 shows an embodiment of a radio frequency (RF) switching circuit;

FIG. 4 shows the structure of the switching element 10A shown in FIG. 3;

FIG. 5 shows the relationship between frequency and insertion loss;

FIG. 6 shows another embodiment of the switching element 10A shown in FIG. 3;

FIG. 7 shows an embodiment of a single-pole double-throw (SPDW) RF switching circuit;

FIG. 8 shows another embodiment of a radio frequency (RF) switching circuit;

FIG. 9 shows the structure of the switching element 10C shown in FIG. 8;

FIG. 10 shows another embodiment of the switching element 10C shown in FIG. 8; and

FIG. 11 shows another embodiment of another single pole dual throw (SPDW) RF switching circuit.

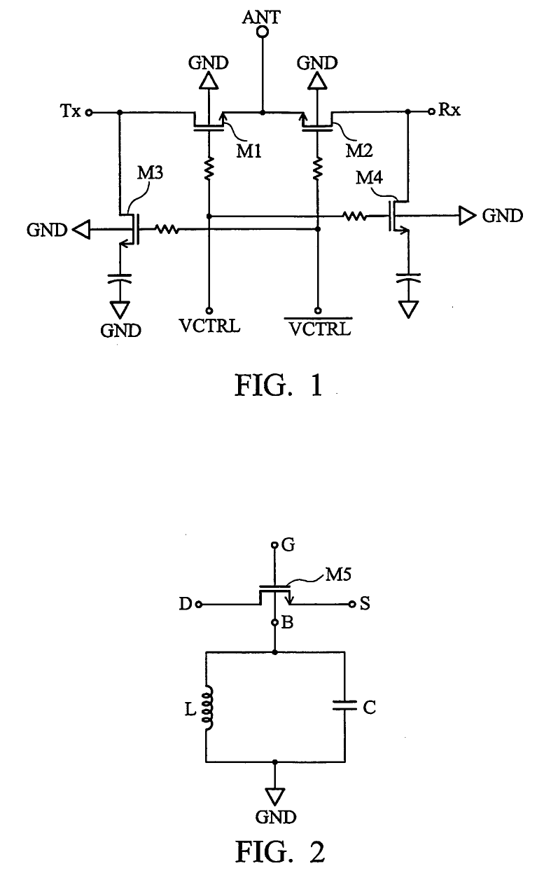

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

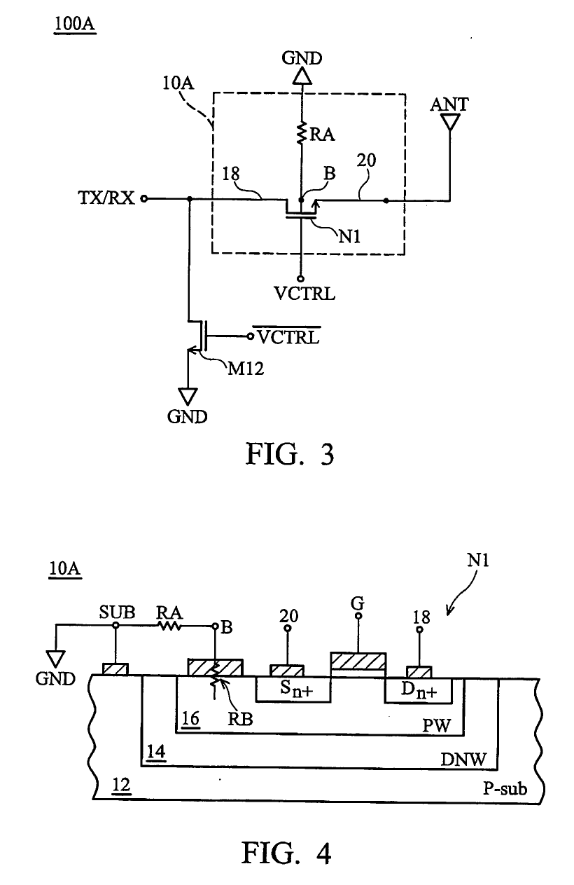

FIG. 3 shows a first embodiment of a radio frequency (RF) switching circuit. As shown, the switching circuit 100A comprises two switching elements 10A and M12. The switching element 10A comprises a first terminal 18 coupled to an output/input terminal TX/RX, a second terminal 20 coupled to an antenna element ANT, a control terminal coupled to a control signal VCTRL and a bulk terminal B coupled to the ground voltage GND through a first external resistive element RA. The switching element M12 comprises a control terminal coupled to an inversion signal of the control signal VCTRL, a first terminal coupled to the ground voltage GND, and a second terminal coupled to the output/input terminal TX/RX. The switching element 10A is turned on, according to the control signal VCTRL, to transmit a signal received by the antenna element ANT to the output/input terminal TX/RX or a signal output from the output/input terminal TX/RX to the antenna element ANT.

FIG. 4 shows the structure of switching element 10A. As shown, the switching element 10A comprises a NMOS element N1 and N type deep well region 14 in a P type substrate 12. The NMOS element N1 comprises a P type well region 16 disposed in the N type deep well region 14, first and second doped regions disposed in the P type well region 16, and a bulk terminal coupled to a ground voltage GND though the external resistive element RA. The N type deep well region 14 is disposed in the substrate 12 to separate the MOS element N1 from the substrate 12.

Because insertion loss can be reduced by increasing bulk resistance approaching to infinite or reducing bulk resistance approaching to zero, the invention utilizes an external resistive element RA with high impedance connected to bulk terminal in series. Accordingly, the resistance between the bulk terminal B and the ground is increased to the total of resistor RB and the external resistive element RA, and isolation between the bulk terminal B and the ground is increased and insertion loss is reduced. If the N type deep well region 14 is omitted, the resistive element RA connected to the bulk terminal B of NMOS element N1 cannot separate signal distortion. Thus, the invention utilizes triple well technology to form an N type deep well region 14 under P type well region 16 of the NMOS element N1 to separate the bulk terminal B from the P type substrate (connected to ground) of the IC (not shown). Compared with the conventional method using multiple contacts, inductors or capacitors, the invention utilizes resistive elements such that area requirement is reduced and there is no bandwidth limitation. In the embodiments of the invention, the resistance of the external resistive element exceeds 1 KΩ, and it exceeds 10 KΩ preferably.

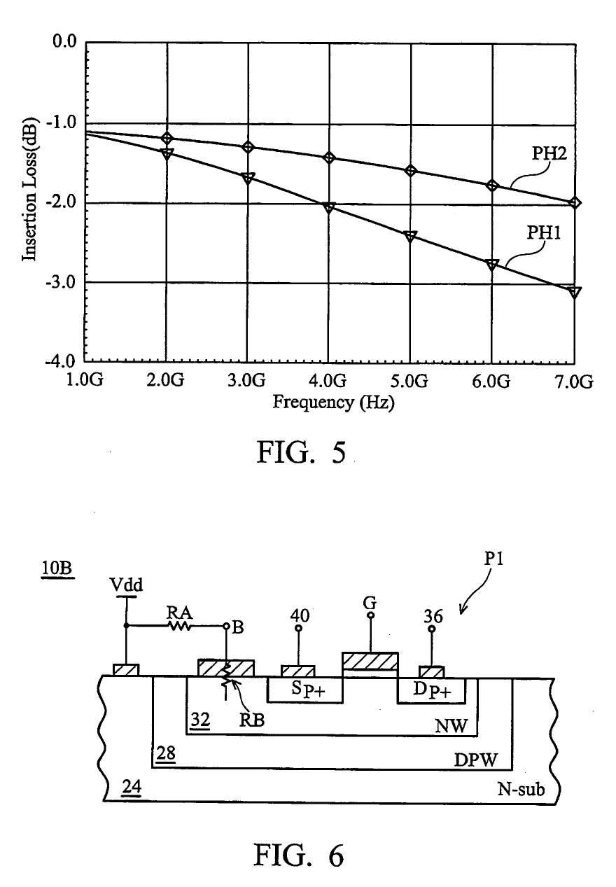

FIG. 5 shows the relationship between frequency and insertion loss. Curve RH1 shows the relationship between frequency and insertion loss of the conventional switching element without external resistor. Curve RH2 shows the relationship between frequency and insertion loss of the switching element with external resistor. As shown, the insertion loss of the switching element can improve 0.5 db when operating at 3 GHz and about 1 dB when operating at 6 GHz.

The switching circuit 10A can also be implemented by a PMOS element and a p type deep well region. FIG. 6 shows another embodiment of the switching circuit. As shown, the switching circuit 10B comprises a PMOS element P1 and a P type deep well region 28. The PMOS element P1 is disposed in an N type substrate 24, and comprises an N type well region 32 disposed in the P type deep well region 28, first and second doped regions D and S disposed in the N type well region 32, and a bulk terminal B coupled to a power voltage (VDD) through an external resistive element RA. The P type deep well region 28 is disposed in the N type substrate 24, separating the PMOS element P1 from the substrate 24. Operations of the switching circuit 10B are similar to those of the switching circuit 10A shown in FIG. 4, and thus, are omitted for simplification.

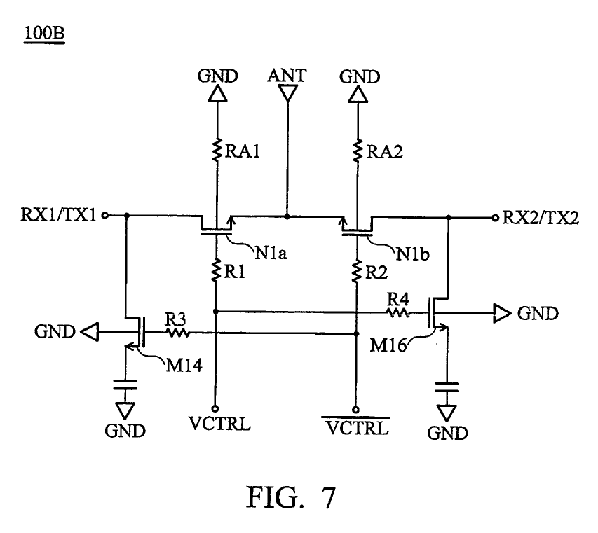

FIG. 7 shows a second embodiment of a single-pole double-throw (SPDW) RF switching circuit. As shown, the switching circuit 100B comprises switching elements N1a, N1b, M14 and M16, in which the switching elements M14 and M16 are normal NMOS transistors, and the switching elements N1a and N1b are both similar to the switching element 10A shown in FIG. 4.

The switching element N1a comprises a drain terminal coupled to an output/input terminal TX1/RX1, a source terminal coupled to an antenna element ANT, a control terminal coupled to a control signal VCTRL through a resistor R1 and a bulk terminal coupled to the ground voltage GND through a first external resistive element RA1. The switching element N1b comprises a drain terminal coupled to an output/input terminal TX2/RX2, a source terminal coupled to an antenna element ANT, a control terminal coupled to an inversion signal \overline{VCTRL} of the control signal VCTRL through a resistor R2 and a bulk terminal coupled to the ground voltage GND through a second external resistive element RA2. The switching element M14 comprises a control terminal coupled to the inversion signal \overline{VCTRL} through a resistor R3, a source terminal coupled to the ground voltage GND through a capacitor, drain terminal coupled to an output/input terminal TX1/RX1, and a bulk terminal coupled to the ground voltage GND. The switching element M16 comprises a control terminal coupled to the control VCTRL through a resistor R4, a source terminal coupled to the ground voltage GND through a capacitor, drain terminal coupled to an output/input terminal TX2/RX2, and a bulk terminal coupled to the ground voltage GND. Resistance of the external resistive elements RA1 and RA2 each exceeds 1 KΩ respectively, and they exceed 10 KΩ preferably.

When the control signal VCTRL is high, the switching element N1a is turned on to transmit a signal received by the antenna element ANT to the output/input terminal TX1/RX1 or a signal output from the output/input terminal TX1/RX1 to the antenna element ANT. The switching element M16 is turned on to pull the voltage level at the output/input terminal TX2/RX2 to the ground voltage, and the switching elements N1b and M14 is turned off. On the contrary, when the control signal \overline{VCTRL} is high, the switching element N1b is turned on to transmit a signal received by the antenna element ANT to the output/input terminal TX2/RX2 or a signal output from the output/input terminal TX2/RX2 to the antenna element ANT. The switching element M14 is turned on to pull the voltage level at the output/input terminal TX1/RX1 to the ground voltage, and the switching elements N1a and M16 are turned off.

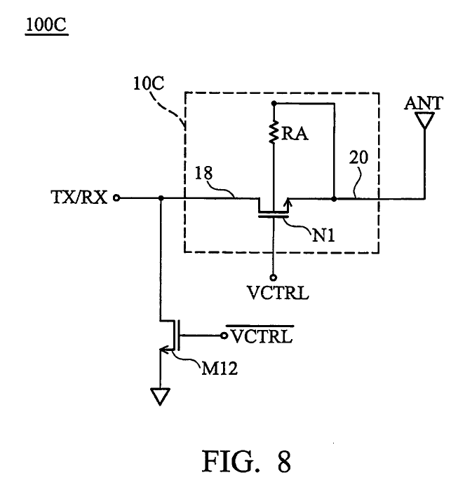

Under negative half periods, the voltage level at drain/source terminal of the MOS transistor is below 0V due to voltage swing. There is a positive bias voltage between the PN junction between the drain/source terminal and the bulk terminal, because the bulk terminal of the MOS transistor is grounded. Thus, signal distortion is induced. In order to solve such problems, the invention also discloses another embodiment of the switching circuits shown in FIG. 8.

As shown, the switching circuit 100C comprises two switching elements 10C and M12. The switching element 10C comprises a first terminal 18 coupled to an output/input terminal TX/RX, a second terminal 20 coupled to an antenna element ANT, a control terminal coupled to a control signal VCTRL and a bulk terminal coupled to the second terminal thereof through an external resistive element RA. The switching element M12 comprises a control terminal coupled to an inversion signal of the control signal VCTRL, a first terminal coupled to the ground voltage GND and a second terminal coupled to the output/input terminal TX/RX and the first terminal 18 of the switching element 10C. The switching element 10C is turned on, according to the control signal VCTRL, to transmit a signal received by the antenna element ANT to the output/input terminal TX/RX or a signal output from the output/input terminal TX/RX to the antenna element ANT.

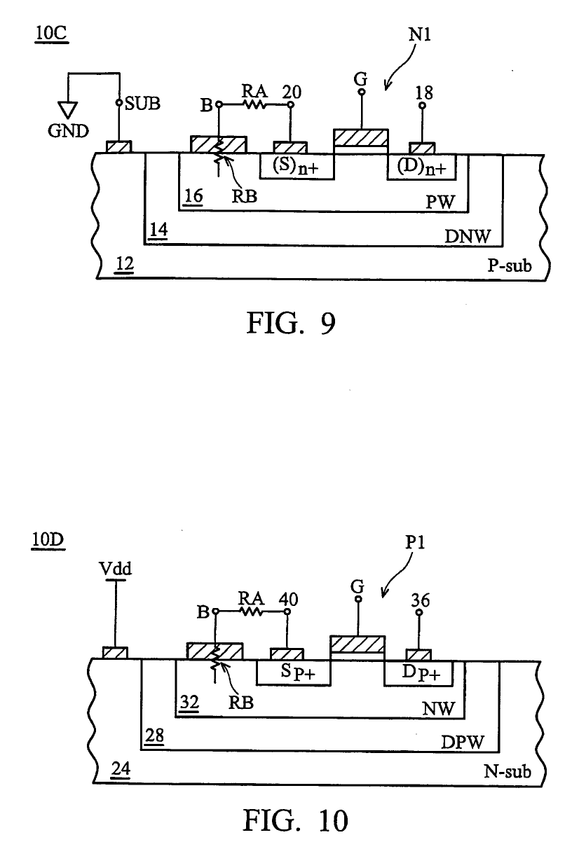

FIG. 9 shows the structure of the switching element 10C. The switching element 10C is similar to the element 10A shown in FIG. 3 except that the resistive element RA is coupled between the bulk terminal B and the source terminal S of the NMOS element N1. Due to the resistive element RA, the total resistance between the ground and the bulk terminal of the switching element 10C is increased to reduce insertion loss thereof. The resistance of the external resistive element RA exceeds 1 KΩ, and it exceeds 10 KΩ preferably.

Further, because no current flows through the bulk terminal of the NMOS element N1, the voltage levels at the source terminal S and the bulk terminal B are the same when the source terminal and the bulk terminal B of the NMOS element N1 are connected to each other. Accordingly, there is no voltage difference between the drain terminal D, the source terminal S and the bulk terminal B of the MOS element N1 under negative half periods. Thus, no forward bias is generated and signal distortion is prevented.

Similarly, the switching element 10C can also be implemented by a PMOS element and a P type deep well region, as shown in FIG. 10. As shown, the switching 10D comprises a PMOS element P1 and a P type deep well region 28, in which the P type deep well region 28 is disposed in the N type substrate 24 to separate the PMOS element 24 and the substrate 24. The PMOS element P1 is disposed in the N type substrate 24, and comprises a source doped region S, a drain doped region D, and a bulk terminal B coupled to the source doped region S thereof through an external resistive element RA. Operations of the switching element 10D are similar to those of the switching element 10A shown in FIG. 3, and thus, are omitted for simplification.

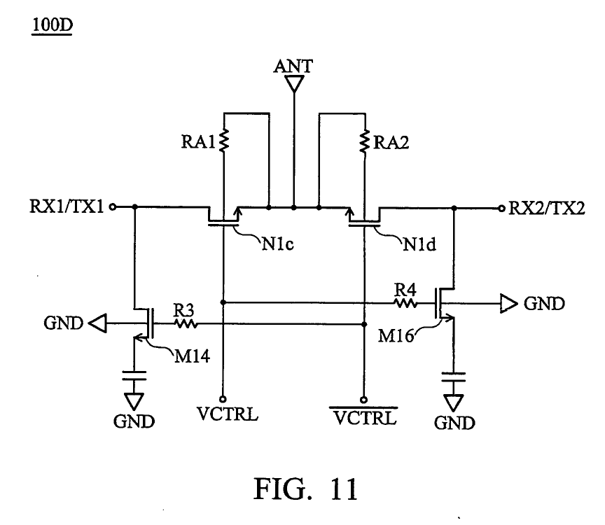

FIG. 11 shows a fourth embodiment of another single pole dual throw (SPDW) RF switching circuit. As shown, the switching circuit 100D comprises switching elements N1c, N1d, M14 and M16, in which the switching elements M14 and M16 are normal NMOS transistors, and the switching elements N1c and N1d both are similar to the switching element 10D shown in FIG. 10.

The switching element N1c comprises a drain terminal coupled to an output/input terminal TX1/RX1, a source terminal coupled to an antenna element ANT, a control terminal coupled to a control signal VCTRL and a bulk terminal coupled to the source terminal thereof through a first external resistive element RA1. The switching element N1d comprises a drain terminal coupled to an output/input terminal TX2/RX2, a source terminal coupled to an antenna element ANT, a control terminal coupled to an inversion signal \overline{VCTRL} of the control signal VCTRL and a bulk terminal coupled to the source terminal thereof through a second external resistive element RA2. The switching element M14 comprises a control terminal coupled to the inversion signal \overline{VCTRL} through a resistor R3, a source terminal coupled to the ground voltage GND through a capacitor, drain terminal coupled to an output/input terminal TX1/RX1, and a bulk terminal coupled to the ground voltage GND. The switching element M16 comprises a control terminal coupled to the control VCTRL through a resistor R4, a source terminal coupled to the ground voltage GND through a capacitor, drain terminal coupled to an output/input terminal TX2/RX2, and a bulk terminal coupled to the ground voltage GND. Resistance of the external resistive elements RA1 and RA2 exceeds 1KU respectively, and they exceed 10 KΩ preferably.

When the control signal VCTRL is high, the switching element N1a is turned on to transmit a signal received by the antenna element ANT to the output/input terminal TX1/RX1 or a signal output from the output/input terminal TX1/RX1 to the antenna element ANT. The switching element M16 is turned on to pull the voltage level at the output/input terminal TX2/RX2 to the ground voltage, and the switching elements N1b and M14 are turned off. On the contrary, when the control signal \overline{VCTRL} is high, the switching element N1b is turned on to transmit a signal received by the antenna element ANT to the output/input terminal TX2/RX2 or a signal output from the output/input terminal TX2/RX2 to the antenna element ANT. The switching element M14 is turned on to pull the voltage level at the output/input terminal TX1/RX1 to the ground voltage, and the switching elements N1a and M16 is turned off.

Due to the external resistive elements, the total resistance between the ground and the bulk terminal is increased, and insertion loss of the switching circuits reduced. Further, because no current flows through the bulk terminal of the switching elements, the voltage levels at the source terminal and the bulk terminal are the same when the source terminal and the bulk terminal of the MOS element are connected to each other. Accordingly, there is no voltage difference between the drain terminal, the source terminal and the bulk terminal of the MOS element under negative half periods. Thus, no forward bias is generated and signal distortion is prevented.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A switching circuit, comprising:
a first MOS element of a first conductive type, disposed in a substrate of a second conductive type, comprising a first terminal coupled to an output/input terminal, a second terminal coupled to an antenna element, a control terminal coupled to a control signal, and a bulk terminal coupled to a first voltage through an external resistor; and
a deep well region of the first conductive type, disposed in the substrate, separating the first MOS element from the substrate.

2. The switching circuit as claimed in claim 1, wherein the first MOS element comprises:
a first well region of the second conductive type disposed in the deep well region and coupled to the bulk terminal;
a first doped region of the first conductive type disposed in the first well region and coupled to the first terminal; and
a second doped region of the second conductive type disposed in the first well region and coupled to the second terminal.

3. The switching circuit as claimed in claim 1, wherein the first conductive type is N type, and the second conductive type is P type.

4. The switching circuit as claimed in claim 3, wherein the first voltage is a ground voltage.

5. The switching circuit as claimed in claim 4, further comprising a second MOS element of the first conductive type, comprising a first terminal coupled to the first terminal of the first MOS element, a second terminal coupled to the ground, and a control terminal coupled to an inversion signal of the control signal.

6. The switching circuit as claimed in claim 1, wherein the first conductive type is P type, and the second conductive type is N type.

7. The switching circuit as claimed in claim 6, wherein the first voltage is a power voltage.

8. The switching circuit as claimed in claim 7, further comprising a second MOS element of the first conductive type, comprising a first terminal coupled to the first terminal of the first MOS element, a second terminal coupled to the power voltage, and a control terminal coupled to an inversion signal of the control signal.

9. A switching circuit, comprising:
a first MOS element of a first conductive type, disposed in a substrate of a second conductive type, comprising a first terminal coupled to an output/input terminal, a second terminal coupled to an antenna element, a control terminal coupled to a control signal, and a bulk terminal;
a deep well region of the first conductive type, disposed in the substrate, separating the first MOS element from the substrate; and
a resistive element coupled between the second terminal and the bulk terminal of the first MOS element.

10. The switching circuit as claimed in claim 9, wherein the first MOS element comprises:
a first well region of the second conductive type disposed in the deep well region and coupled to the bulk terminal;
a first doped region of the first conductive type disposed in the first well region and coupled to the first terminal; and
a second doped region of the second conductive type disposed in the first well region and coupled to the second terminal.

11. The switching circuit as claimed in claim 9, wherein the first conductive type is N type, and the second conductive type is P type.

12. The switching circuit as claimed in claim 11, further comprising a second MOS element of the first conductive type, comprising a first terminal coupled to the first terminal of the first MOS element, a second terminal coupled to ground, and a control terminal coupled to an inversion signal of the control signal.

13. The switching circuit as claimed in claim 9, wherein the first conductive type is P type, and the second conductive type is N type.

14. The switching circuit as claimed in claim 13, further comprising a second MOS element of the first conductive type, comprising a first terminal coupled to the first terminal of the first MOS element, a second terminal coupled to a power voltage, and a control terminal coupled to an inversion signal of the control signal.

15. A switching circuit, comprising:
a deep well region of the first conductive type, disposed in the substrate of a second conductive type;
first and second MOS elements of a first conductive type, disposed in the deep well region of the first, each comprising a first terminal coupled to a first output/input terminal, a second terminal coupled to an antenna element, a control terminal coupled to a control signal, and a bulk terminal coupled to a first voltage through a first external resistor; and
a third MOS element of a second conductive type, comprising a first terminal coupled to a second output/input terminal, a second terminal coupled to the antenna element, a control terminal coupled to an inversion signal of the control signal, and a bulk terminal coupled to the first voltage through a second external resistor, wherein the deep well region separates the first and second MOS elements of the first conductive type from the substrate of the second conductive type.

16. The switching circuit as claimed in claim 15, wherein the first and second MOS elements each comprise:
a first well region of the second conductive type disposed in the deep well region and coupled to the bulk terminal;
a first doped region of the first conductive type disposed in the first well region and coupled to the first terminal; and
a second doped region of the second conductive type disposed in the first well region and coupled to the second terminal.

17. The switching circuit as claimed in claim 15, wherein the first conductive type is N type, and the second conductive type is P type.

18. The switching circuit as claimed in claim 17, wherein the first voltage is a ground voltage.

19. The switching circuit as claimed in claim 18, further comprising a fourth MOS element of the first conductive type, comprising a first terminal coupled to the first terminal of the first MOS element, a second terminal coupled to the ground voltage, and a control terminal coupled to an inversion signal of the control signal.

20. A switching circuit, comprising:
a deep well region of the first conductive type, disposed in the substrate of a second conductive type;
a first MOS element of a first conductive type, disposed in deep well region, comprising a first terminal coupled to a first output/input terminal, a second terminal coupled to an antenna element, a control terminal coupled to a control signal, and a bulk terminal;
a first resistive element coupled between the second terminal and the bulk terminal of the first MOS element;
a second MOS element of the first conductive type, comprising a first terminal coupled to a second output/input terminal, a second terminal coupled to the antenna element, a control terminal coupled to an inversion signal of the control signal, and a bulk terminal, wherein the deep well region separates the first and second MOS elements from the substrate; and
a second resistive element coupled between the second terminal and the bulk terminal of the second MOS element.

21. The switching circuit as claimed in claim 20, wherein the first and second MOS elements each comprise:
a first well region of the second conductive type disposed in the deep well region and coupled to the bulk terminal;
a first doped region of the first conductive type disposed in the first well region and coupled to the first terminal; and
a second doped region of the second conductive type disposed in the first well region and coupled to the second terminal.
